(19) United States
(12) Patent Application Publication
(10) Pub. No.: US 2008/0066899 A1
(43) Pub. Date: Mar. 20, 2008

(54) TAPE-LIKE HEAT SINK

(76) Inventor: ZHAO-REN WANG, Tainan Hsien (TW)

Correspondence Address: LEONG C LEI, PMB # 1008, 1867 YGNACIO VALLEY ROAD, WALNUT CREEK, CA, 94598, US

(21) Appl. No.: 11/532,116

(22) Filed: Sep. 15, 2006

(51) Int. Cl. H05K 7/20

(52) U.S. Cl. 165/185

(57) ABSTRACT

A tape-like heat sink is disclosed. The heat sink is characterized in that a base section which is flexural is mounted to the heat sink, and the base is matrix distribution of protrusions for heat dissipation, and each of the protrusions is provided with a thin layer, thereby the thin film is conveniently flexural for heat dissipation.

### BACKGROUND OF THE INVENTION

(a) Technical Field of the Invention

The present invention relates to heat sink, and in particular, a tape-like, flexural and cuttable heat sink. The hear sink can be rolled up for storage.

(b) Brief Description of the Prior Art

Heat sinks are used to adhere to chips or high power capacitors in dissipating heat energy generated from chips or high power capacitors into the air. FIGS. 1 and 2 show conventional heat sink. The plate-like heat sink 1 is made based on the size of the object where heat is to be dissipated. When the heat sink 1 is manufactured, it is adhered to the position of the heat dissipation object 2, and the heat sink 1 is firmly adhered. When the size of the heat dissipation object 2 changes, the heat sink 1 has to be re-designed and re-fabricated. Thus, the sizes of the heat sink are many and therefore, the cost of manufacturing the heat sink increases as different molds of varying sizes are required. This will also increase the need of storage for heat sink 1. It is laborious and a waste of time in the fabrication process.

In view of the drawback, it is an object of the present invention to provide a tape-like heat sink which mitigates the above drawback.

### SUMMARY OF THE INVENTION

Accordingly, it is an object of the present invention to provide a tape-like heat sink, characterized in that a base section which is flexural is mounted to the heat sink, and the base is matrix distribution of protrusions for heat dissipation, and each of the protrusions is provided with a thin layer, thereby the thin film is conveniently flexural for heat dissipation.

Yet still a further object of the present invention is to provide a tape-like heat sink, wherein the thin film is cuttable into appropriate size as heat sink.

Still a further object of the present invention is to provide a tape-like heat sink, wherein the opposite side of the protrusion is coated with heat conduction adhesive layer which is further mounted with a protective layer. The foregoing objects and summary provide only a brief introduction to the present invention. To fully appreciate these and other objects of the present invention as well as the invention itself, all of which will become apparent to those skilled in the art, the following detailed description of the invention and the claims should be read in conjunction the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view of a conventional heat sink.

FIG. 2 is a schematic elevation view of the conventional heat sink of FIG. 1.

FIG. 3 is an exploded view of the heat sink showing a partial of the heat sink being cut in accordance with the present invention.

FIG. 4 is a schematic view showing the cutting of a partial of the heat sink in accordance with the present invention.

FIG. 5 is another schematic view showing the cutting of a partial of the heat sink in accordance with the present invention.

FIG. 6 is a perspective schematic view showing the flexural heat sink of the present invention.

FIG. 7 is a schematic view where the heat sink is stacked in accordance with the present invention.

FIG. 8 is a schematic view showing the rolling up of the heat sink of the present invention.

FIG. 9 schematically shows the application of the heat sink of the present invention onto a LED.

FIG. 10 schematically shows the application of the heat sink of the present invention onto a curved float.

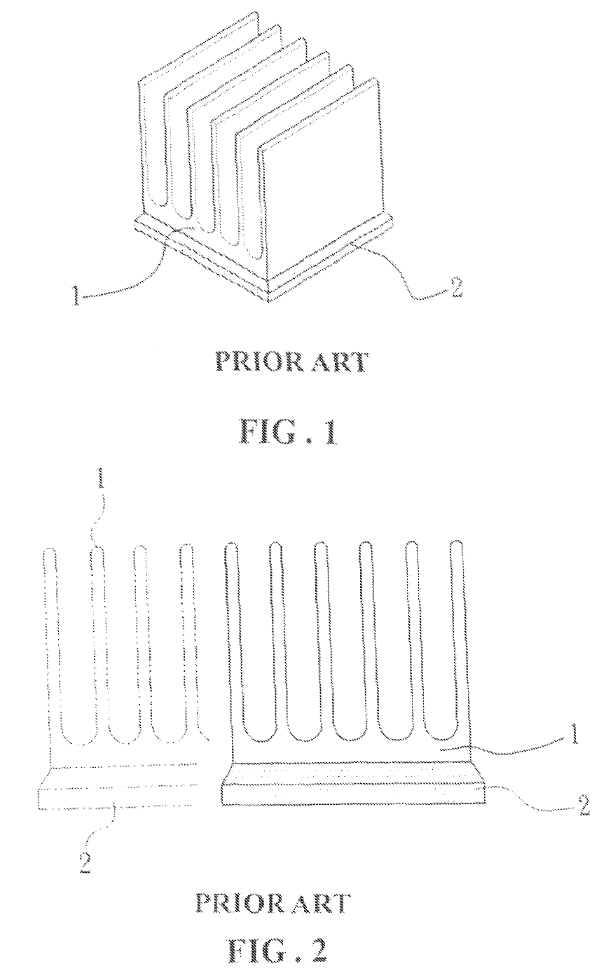

### DETAILED DESCRIPTION OF THE PREFERRED EMBODIMENT

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

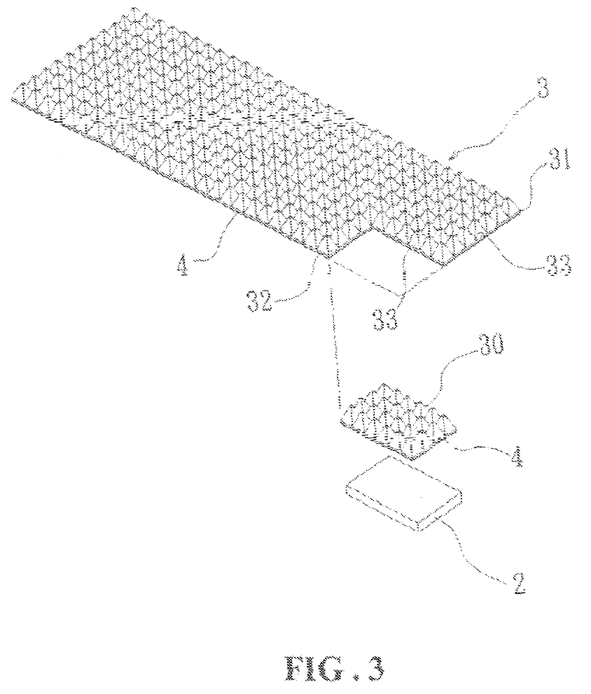

Referring to FIG. 3, there is shown a perspective view of a heat sink 3 comprising a base section 31, and a plurality of protrusions 33 arranged in matrix arrangement or exposed on the base section 31. In between each of the protrusions 32, a thin film 33 is formed and the side of the base section 31 opposite to the position of the protrusions 32 is coated with heat conductive adhesive layer 4. In implementation of the heat sink 3, the heat sink 3 is cut along the thin film 33. The area of the partially cut heat sink 3 is corresponding to the size or area of the heat dissipation objects such as the size of a chip or a high power capacitor, or the like. Heat conductive adhesive layer 4 is attached to the heat dissipation object and the attachment is firmly secured.

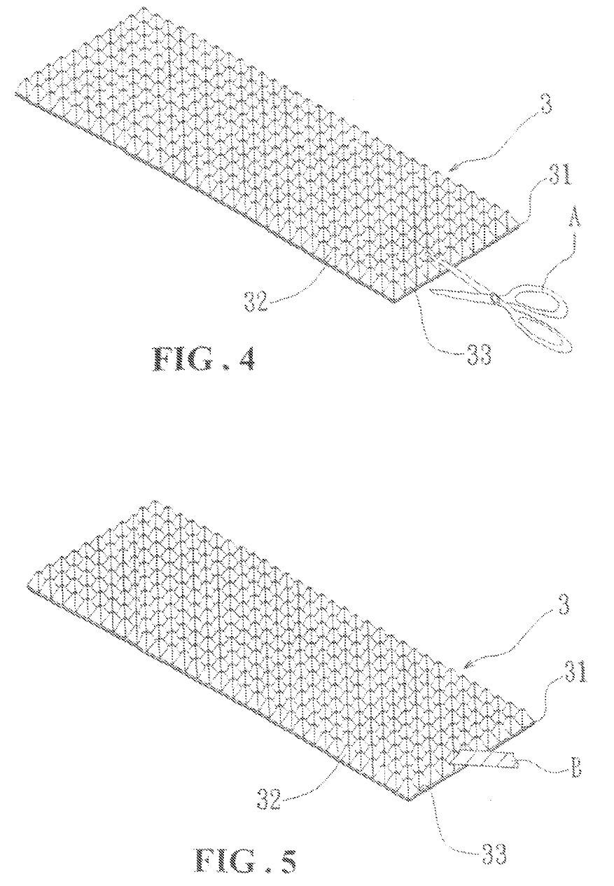

As shown in FIGS. 4 and 5, the heat sink 3 is cut along the thin film 33 into an appropriate size, the cutting process is done with a cutter A (shown in FIG. 4) or the heat sink 3 is cut using a knife B (as shown in FIG. 5).

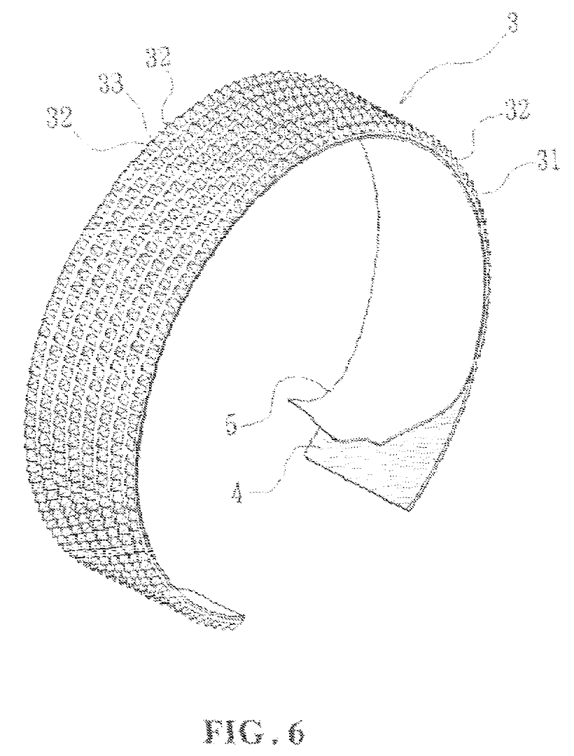

The heat sink 3 is flexural and it is rolled up for storage. As shown in FIG. 6, a protective layer 5 is attached to the heat conductive adhesive layer 4. Thus, before heat sink 3 is used, the protective layer 5 prevents the adhesive layer 4 from sticking onto other object. The heat sink 3 is rolled up for storage or for conveniently keeping with the protective layer 5 being attached to the adhesive layer 4.

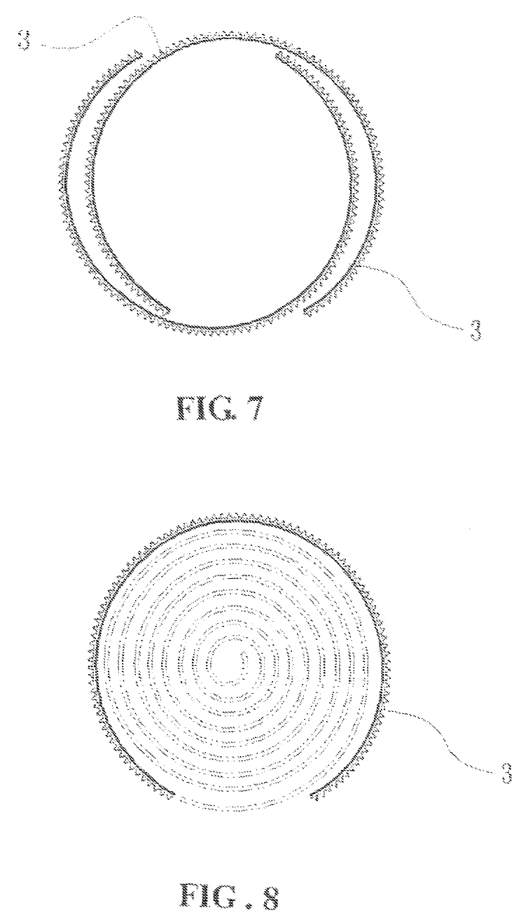

Referring to FIGS. 7 and 8, the heat sink 3 could be stacked by coiling to each other for storage and rolled up. These arrangements save storage space.

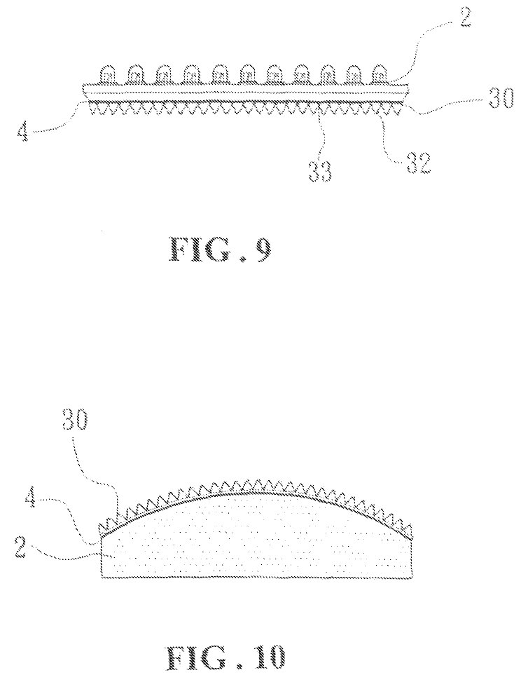

FIGS. 9 and 10 show the application of the heat sink 3 of the present invention. In these cases, a LED module or a curved object is to be mounted with the heat sink 3. First, an appropriate size heat sink 3 is cut along the thin film 33. The size is corresponding to that of the heat dissipation object 2 (for example, LED module). The protective layer 5 is removed and the exposed heat conductive adhesive layer 4 is adhered onto the heat dissipation object (as shown in FIGS. 9 and 10). The heat sink 30 after being mounted onto the heat dissipation object 2, for example a chip, corresponds to the shape of the heat dissipation object 2. The heat sink 30 can be bent a little or presses to take the shape of the heat dissipation object 2 after it is adhered onto the heat dissipation object 2.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A tape-like heat sink which is flexural and cuttable, characterized in that a base section which is flexural is mounted to the heat sink, and the base is matrix distribution of protrusions for heat dissipation, and each of the protrusions is provided with a thin layer, whereby the thin film is conveniently flexural for heat dissipation.

2. The tape-like heat sink of claim 1, wherein the thin film is cuttable into appropriate size as heat sink.

3. The tape-like heat sink of claim 1, wherein the opposite side of the protrusion is coated with heat conduction adhesive layer which is further mounted with a protective layer.
